(19) United States
(12) Patent Application Publication
(10) Pub. No.: US 2025/0016935 A1
(43) Pub. Date: Jan. 9, 2025

(54) SYSTEMS AND METHODS FOR A LOW-PROFILE RECTIFIER FOR EV WIRELESS CHARGING USING EMBEDDED PCB

(71) Applicant: Toyota Motor Engineering & Manufacturing North America, Inc., Plano, TX (US)

(72) Inventors: Yanghe Liu, Ann Harbor, MI (US); Feng Zhou, Ann Harbor, MI (US); Ercan M. Dede, Ann Harbor, MI (US)

(73) Assignees: Toyota Motor Engineering & Manufacturing North America, Inc., Plano, TX (US); Toyota Jidosha Kabushiki Kaisha, Toyota-Shi (JP)

(21) Appl. No.: 18/346,566

(22) Filed: Jul. 3, 2023

(51) Int. Cl. H05K 3/46; H05K 3/42

(52) U.S. Cl. CPC H05K 3/4673; H05K 3/423; H05K 3/429

(57) ABSTRACT

A method, computer program product, and apparatus for a rectifier. The rectifier may be fabricated, wherein fabricating the rectifier may include fabricating a power device area in a printed circuit board (PCB). Fabricating the rectifier may include fabricating a passive component area in the PCB. Fabricating the rectifier may include fabricating an inductor area in the PCB, wherein each component of the power device area, the passive component area, and copper windings of the inductor area may be entirely embedded within the PCB. One or more ferrite blocks may be assembled into the PCB.

### BACKGROUND

Electrical vehicles (EV) are great for the environment, as they may reduce air pollution and greenhouse gas emissions. The batteries of EVs may be charged using specialized plugs or may be charged wirelessly. Some wireless charging systems operate by having an inductive receiver pad wirelessly receive AC power energy from a transmitter. A rectifier converts AC power into DC power to charge the vehicle's battery. Conventional rectifiers for wireless power transfer use bulky components, such as capacitors and inductors, which may lead to a large total volume of the rectifier.

### BRIEF SUMMARY OF DISCLOSURE

In one example implementation, a method, performed by one or more computing devices, may include but is not limited to fabricating a rectifier, wherein fabricating the rectifier may include fabricating a power device area in a printed circuit board (PCB). Fabricating the rectifier may include fabricating a passive component area in the PCB. Fabricating the rectifier may include fabricating an inductor area in the PCB, wherein each component of the power device area, the passive component area, and copper windings of the inductor area may be entirely embedded within the PCB. One or more ferrite blocks may be assembled into the PCB.

One or more of the following example features may be included. Fabricating the rectifier may further include fabricating, under the active power device area, a plurality of vias connecting a copper substrate to one or more copper layers of the PCB. The one or more copper layers of the PCB may extend beyond the power device area and the passive component area. The power device area may be located in a center portion of the PCB. PCB winding inductors may radially surround the power device area. The power device area may be located in a corner portion of the PCB. A cold plate may be attached to a bottom copper layer of the PCB.

In another example implementation, a computer program product may reside on a computer readable storage medium having a plurality of instructions stored thereon which, when executed across one or more processors, may cause at least a portion of the one or more processors to perform operations that may include but are not limited to fabricating a rectifier, wherein fabricating the rectifier may include fabricating a power device area in a printed circuit board (PCB). Fabricating the rectifier may include fabricating a passive component area in the PCB. Fabricating the rectifier may include fabricating an inductor area in the PCB, wherein each component of the power device area, the passive component area, and copper windings of the inductor area may be entirely embedded within the PCB. One or more ferrite blocks may be assembled into the PCB.

One or more of the following example features may be included. Fabricating the rectifier may further include fabricating, under the active power device area, a plurality of vias connecting a copper substrate to one or more copper layers of the PCB. The one or more copper layers of the PCB may extend beyond the power device area and the passive component area. The power device area may be located in a center portion of the PCB. PCB winding inductors may radially surround the power device area. The power device area may be located in a corner portion of the PCB. A cold plate may be attached to a bottom copper layer of the PCB.

In another example implementation, an apparatus may include but is not limited to a rectifier. The rectifier may include a power device area in a printed circuit board (PCB). The rectifier may include a passive component area in the PCB. The rectifier may include an inductor area in the PCB, wherein each component of the power device area, the passive component area, and copper windings of the inductor area may be entirely embedded within the PCB. The rectifier may include one or more ferrite blocks in the PCB.

One or more of the following example features may be included. The rectifier may further include a plurality of vias under the active power device area connecting a copper substrate to one or more copper layers of the PCB. The one or more copper layers of the PCB may extend beyond the power device area and the passive component area. The power device area may be located in a center portion of the PCB. PCB winding inductors may radially surround the power device area. The power device area may be located in a corner portion of the PCB. A cold plate may be attached to a bottom copper layer of the PCB

The details of one or more example implementations are set forth in the accompanying drawings and the description below. Other possible example features and/or possible example advantages will become apparent from the description, the drawings, and the claims. Some implementations may not have those possible example features and/or possible example advantages, and such possible example features and/or possible example advantages may not necessarily be required of some implementations.

### BRIEF DESCRIPTION OF DRAWINGS

FIG. 1 is an example diagrammatic view of a rectifier;

FIG. 2 is an example flowchart of an assembly process according to one or more example implementations of the disclosure;

FIG. 3 is an example diagrammatic view of a rectifier according to one or more example implementations of the disclosure;

FIG. 4 is an example flowchart of an assembly process according to one or more example implementations of the disclosure;

FIG. 5 is an example diagrammatic view of different areas of a rectifier according to one or more example implementations of the disclosure;

FIG. 6 is an example diagrammatic view of a PCB inductor winding design layout of a rectifier according to one or more example implementations of the disclosure;

FIG. 7 is an example flowchart of an assembly process according to one or more example implementations of the disclosure;

FIG. 8 is an example diagrammatic view of a layered structure of a rectifier according to one or more example implementations of the disclosure;

FIG. 9 is an example diagrammatic view of an enhanced thermal dissipation design according to one or more example implementations of the disclosure;

FIG. 10 is an example diagrammatic view of a heat spreading visualization of a rectifier according to one or more example implementations of the disclosure; and

FIG. 11 is an example diagrammatic view of a rectifier according to one or more example implementations of the disclosure.

Like reference symbols in the various drawings may indicate like elements.

### DETAILED DESCRIPTION

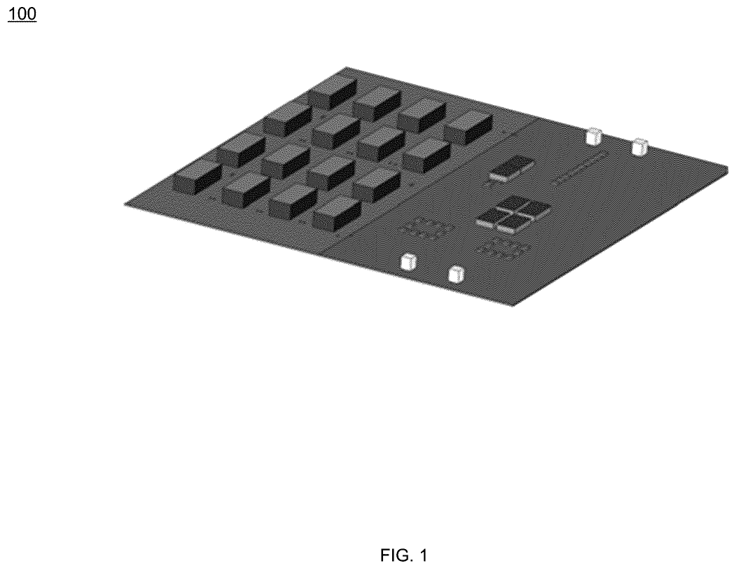

Electrical vehicles (EV) are great for the environment, as they may reduce air pollution and greenhouse gas emissions. The batteries of EVs may be charged using specialized plugs or may be charged wirelessly. Some wireless charging systems operate by having an inductive receiver pad wirelessly receive AC power energy from a transmitter. A rectifier converts AC power into DC power to charge the vehicle's battery. Conventional rectifiers for wireless power transfer use bulky components, such as capacitors and inductors, which may lead to a large total volume of the rectifier. Referring at least to FIG. 1, an improved design of a rectifier 100 is shown using a hybrid metal core printed circuit board (PCB) and FR4 PCB winding inductor. Compared to the above-noted conventional rectifier, this one separates the inductance part and the power loop part by using two different types of PCB. For the inductor side, the PCB may be an 8-layer PCB board with PCB windings embedded inside the board. For the power side, the PCB may be a metal PCB that is good for thermal dissipation. However, the power side occupies a lot of planar space because of the use of surface mount components to reduce thickness. The main contributor to the thickness is the ferrite core from the inductor side.

As well, installation of wireless charging system in an EV typically requires extra space under the chassis where the space limitation is large. This limitation draws back the adoption of the wireless charging system. The rectifier is one of the key power electronics devices in the receiver assembly, which is mainly for converting AC power from the coil to DC power for battery charging. Compared to planar space, vertical space design is more critical to add wireless charging, as the gap between the ground and receiver will affect coil-to-coil coupling, which is an essential influence factor determining power transfer efficiency and quality.

Therefore, to further reduce the thickness of the rectifier, the key challenge may be how to reduce the thickness of the inductor ferrite core by adjusting the design of the power side for more space for inductors. With a given planar size limitation, more space for inductance will enable an increasing number of inductors using smaller size components. Therefore, as will be discussed in greater detail below, the present disclosure may utilize embedded printed circuit board (PCB) technology for designing a super compact low-profile rectifier for EV inductive wireless charging. The present disclosure may do this by minimizing the thickness of the rectifier for lowering anxiety of vertical space sensitivity, using embedded PCB and planar magnetics inductors.

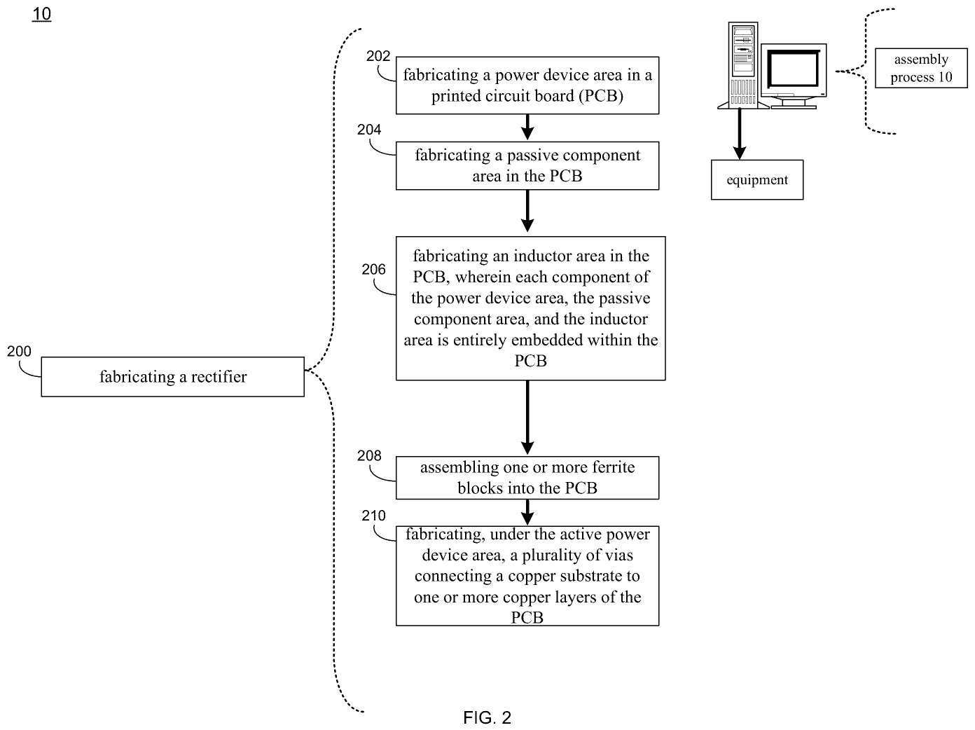

As discussed above and referring also at least to the example implementations of FIGS. 2-11, assembly process 10 may fabricate 200 a rectifier, wherein fabricating the rectifier may include fabricating 202 a power device area in a printed circuit board (PCB). Fabricating the rectifier may include assembly process 10 fabricating 204 a passive component area in the PCB. Fabricating the rectifier may include assembly process 10 fabricating 206 an inductor area in the PCB, wherein each component of the power device area, the passive component area, and the inductor area may be entirely embedded within the PCB. Assembly process 10 may assemble 208 one or more ferrite blocks into the PCB.

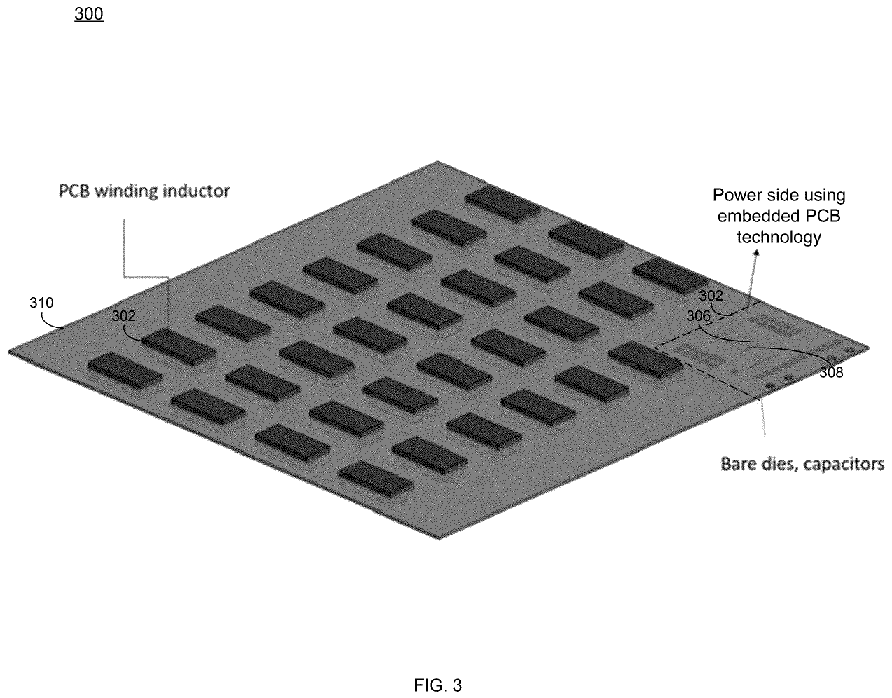

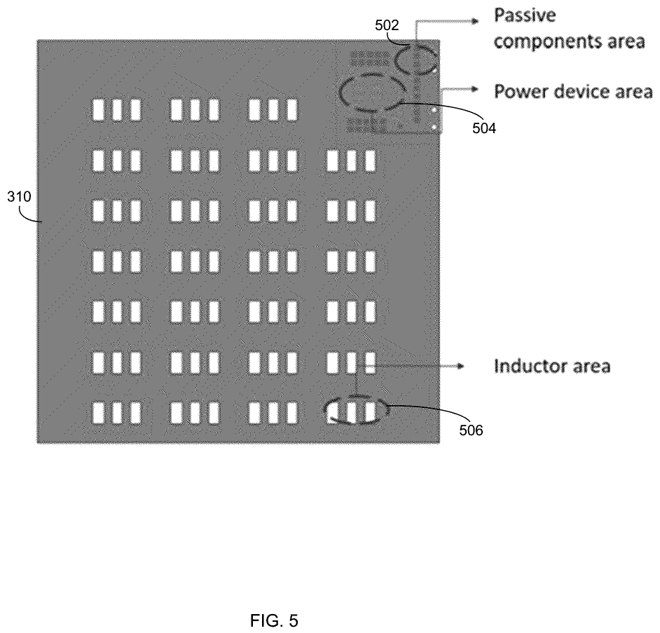

In some implementations, assembly process 10 may fabricate 200 a rectifier, wherein fabricating the rectifier may include fabricating 202 a power device area in a printed circuit board (PCB), fabricating 204 a passive component area in the PCB, and fabricating 206 an inductor area in the PCB, wherein each component of the power device area, the passive component area, and copper windings of the inductor area may be entirely embedded within the PCB. For instance, and referring at least to the example implementation of FIG. 3, an example rectifier (e.g., rectifier 300) is shown, which further reduces the thickness (e.g., 350 mm×350 mm×<10 mm in this example) of prior rectifiers. As can be seen at least from FIGS. 3-5, rectifier 300 may include PCB winding inductors (e.g., PCB winding inductor 302), a power side (e.g., power side 304 using embedded PCB technology), and bare dies and capacitors (e.g., bare dies 306 and capacitors 308), as well as the PCB (e.g., PCB 310). The inductor generally consists of two parts, copper windings and ferrite core. The windings are entirely embedded in the PCB in this case and the ferrite core are assembled separately. Assembling ferrite should generally be the last step and done after the whole PCB board is fabricated properly. The whole PCB includes designed copper layers and embedded components. FIG. 5 shows a clearer example of the passive components area (e.g., passive components area 502), power device area (e.g., power device area 504) and inductor area (e.g., inductor area 506). In some implementations, the power level for AC to DC conversion may reach 11 kW or even higher. By utilizing embedded PCB technology, the electronic components are mounted directly into the PCB board without individual component packaging, e.g., bare dies. For clarity, bare dies are needed and necessary. In conventional packaging, the commercial power device is prepackaged. The bare die is inside the package with a large volume enclosure. In the present disclosure, those well-packaged devices are not used but only the core part, bare die, inside which has a full electrical function. Those bare dies are fragile, usually a thin slice of semiconductor, and cannot be directly used as surface-mounted devices. But they can be embedded into the PCB. So that we don't need any other packaging materials to protect and we can save a lot of volumes. In summary, using embedded technology is to remove all unnecessary packaging materials from electronic devices for size reduction. This technology allows for the creation of smaller and more efficient electronic devices, as the PCB serves as structural support for the components as well as the interconnections between them.

In some implementations, the whole board may be an 8-layer PCB (as in the present example) with a pre-built winding structure for more inductors and an inner structure for the power side. It will be appreciated that an N-layer PCB may also be used. Since power side 304 space is significantly reduced, in this example, 75% smaller, the inductance side can have smaller components spreading over the planar space. Therefore, the ferrite core can be downsized as well.

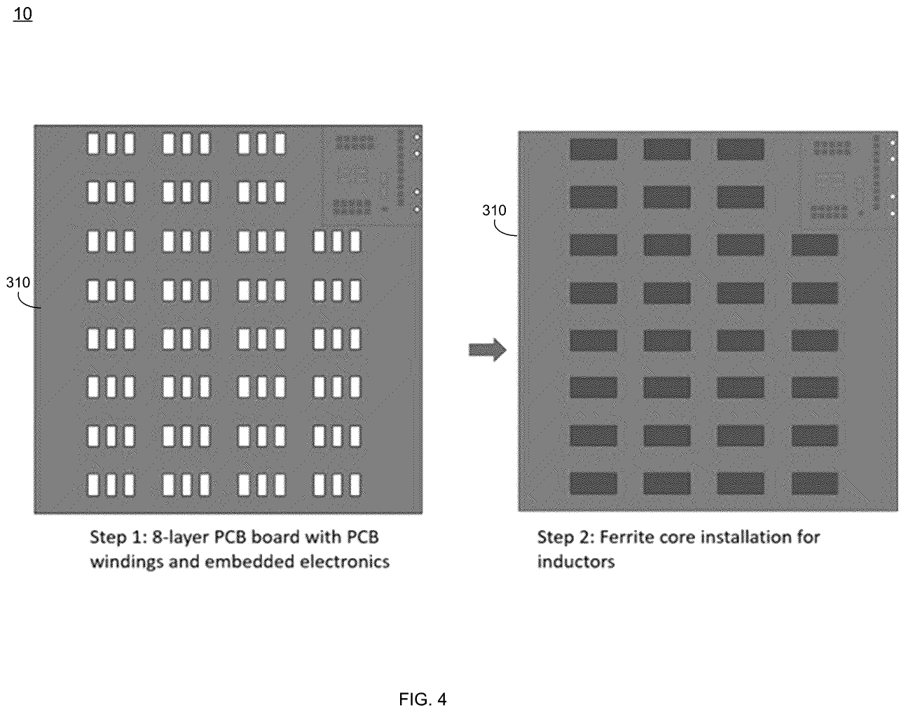

To fabricate such a rectifier, there may be two general steps as shown in the example implementation of FIG. 4, which may be accomplished by assembly process 10. In step 1, the PCB has fabricated with through-all cavities for inductor ferrite core assembly and embedding electronics components for the power loop. This step may be done via a fully automated process without manual effort, although manual effort may be used without departing from the scope of the present disclosure. In some implementations, assembly process 10 may assemble 208 one or more ferrite blocks into the PCB. For instance, as shown in step 2, assembly process 10 may assemble prefabricated ferrite blocks into the PCB board.

The process of fabricating the embedded PCB in step 1 typically involves several sub-steps including design, drilling, etching, lamination, and soldering (there may be additional steps for specific applications and requirements). In the design process, the components' placement and layout of the copper may be determined. For this example 8-layer board, there are three key design areas, which are power devices area 504, passive component area 502, and inductor area 506. As can be seen at least from FIG. 5, in some implementations, the power device area may be located in a corner portion of the PCB.

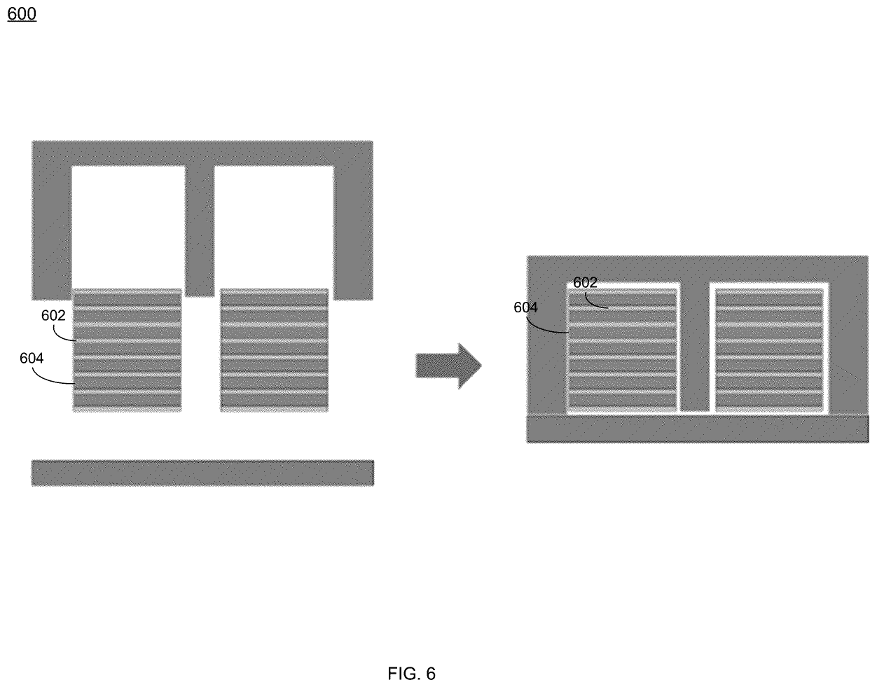

As seen in the example implementation of FIG. 6, an example PCB inductor winding design layout 600 is shown. In the example, copper traces (e.g., copper traces 602) acting as copper wires are designed in this area, and all 8 layers (e.g., layers 604) are covered with thin copper with predesigned cavities.

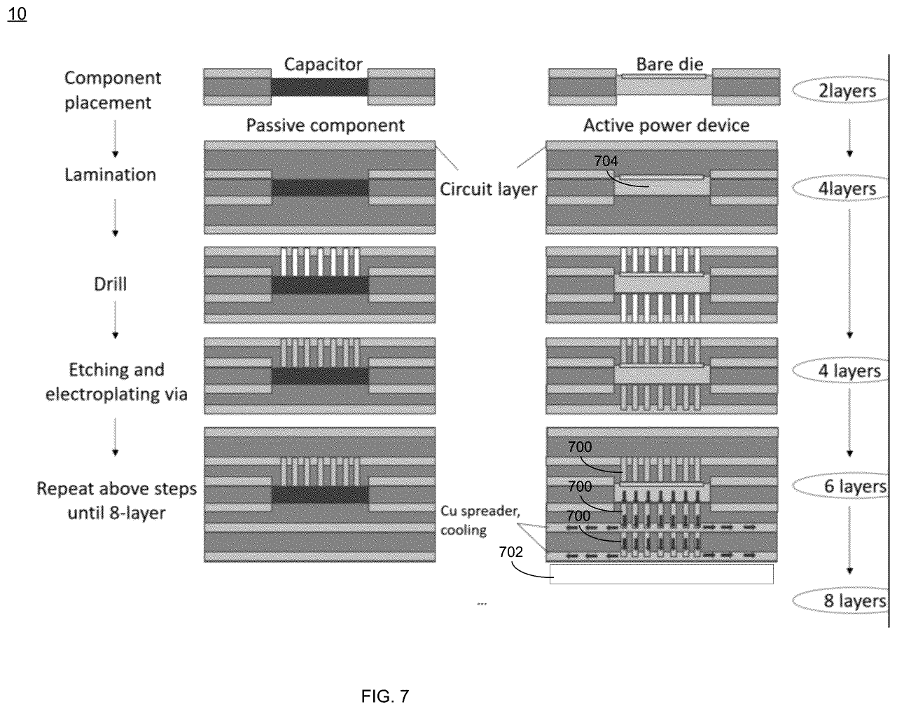

For the passive components area and power device area design, there are similarities in terms of the fabrication process. But there is a slight difference due to different requirements for cooling. Active power devices are the heat-generating components that need extra countermeasures to spread heat. As seen in the example implementation of FIG. 7, the fabricating process of assembly process 10 of these two areas is described step by step. Since the original rectifier only needs one single layer for circuit connection routing, there is only one copper layer above the components for electrical connection. In most cases of other embedded electronics applications, there may be more copper layers for electrical connection. In some implementations, fabricating the rectifier may further include fabricating 210, under the active power device area, a plurality of vias connecting a copper substrate to one or more copper layers of the PCB. For instance, underneath the active power device 704, there are extra vias (e.g., via 700) connecting the copper substrate to PCB copper layers for spreading heat generated from bare dies. Depending on the target number of layers of the board, the number of copper spreader layers could vary. In some implementations, a cold plate may be attached to a bottom copper layer of the PCB. For instance, if necessary, an extra cold plate (e.g., cold plate 702) with active cooling can be attached to the bottom copper spreader layer for cooling enhancement.

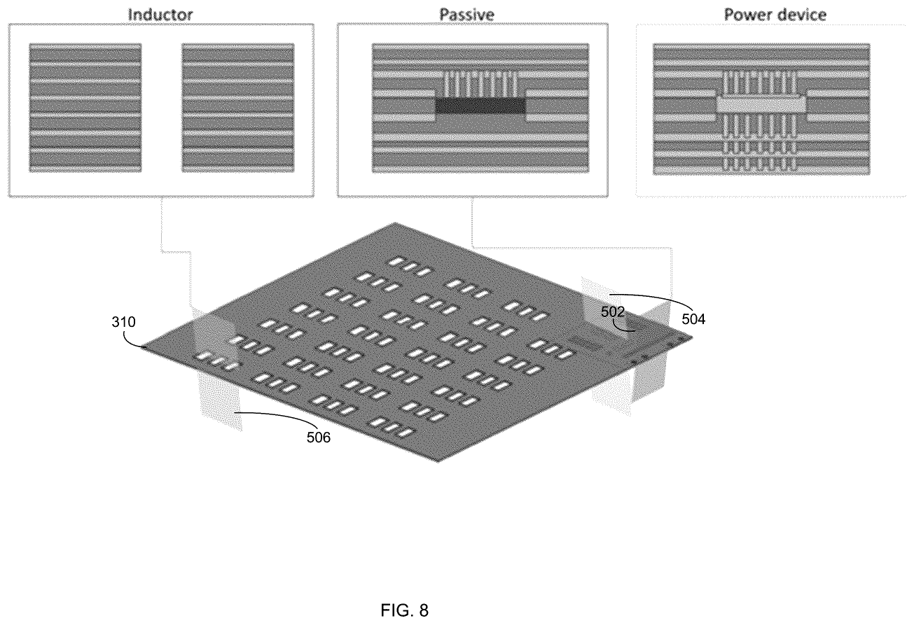

In the example implementation of FIG. 8, there is shown the final layer structure of the three key areas (e.g., passive components area 502, power device area 504 and inductor area 506). Please note that the circuit layer may be the same copper pattern as it in a “regular” PCB board. The copper spreader layer may be just a plain layer without any patterns. As can be seen from FIG. 8, each component of the power device area, the passive component area, and the inductor area may be entirely embedded within the PCB (i.e., embedded between layer 1 and layer 8 of the PCB, such that no portion of those components are above the plane of layer 1 or below the plane of layer 8.

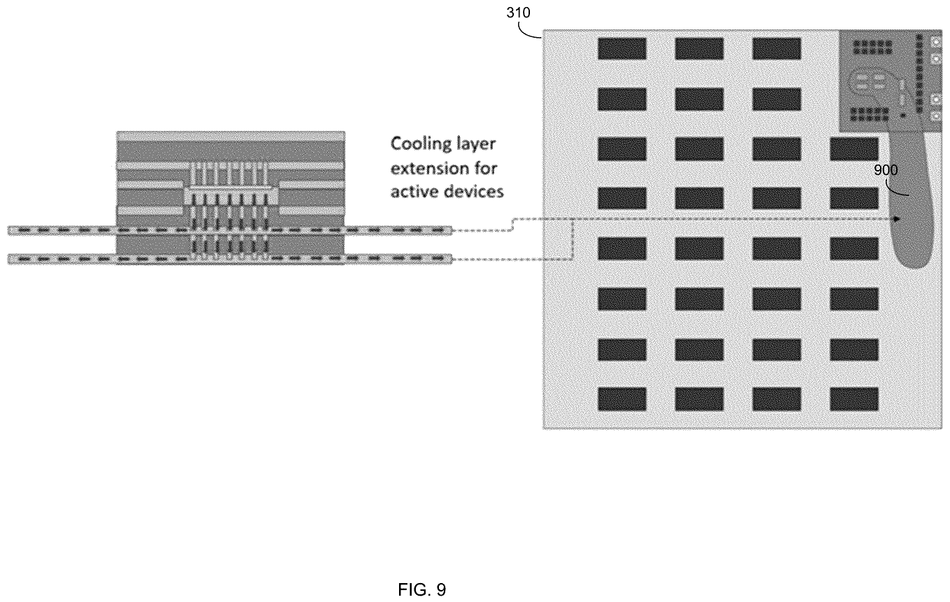

In some implementations, the one or more copper layers of the PCB may extend beyond the power device area and the passive component area. For instance, and referring to the example implementation of FIG. 9 (as well as again to FIG. 7), to enhance thermal dissipation in the embedded power device area, an extension of the copper spreading layer into the spare area (e.g., spare area 900) can maximize the surface area for heat transfer to the ambient. As shown in FIG. 9, the copper layers underneath the power device can extend to the right edge side spare area for higher heat dissipation. The extended copper area is functioning as a heat redistribution plane but is embedded inside the PCB without requiring extra installation space.

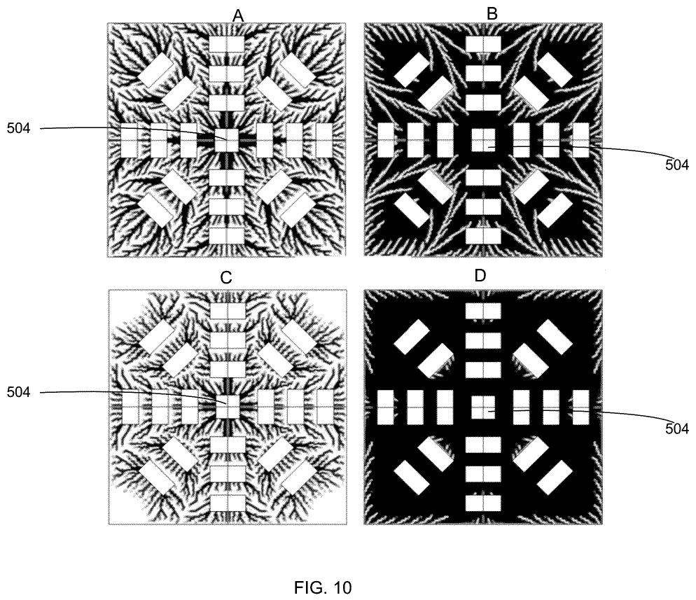

In some implementations, the power device area may be located in a center portion of the PCB. For instance, another case to utilize a spare area for heat spreading while minimizing weight is shown in the example implementation of FIG. 10. As can be seen, there is shown a tree-like with 40% Cu material (A), tree-like with 70% Cu material (B), lamellar with 30% Cu material (C), and lamellar with 85% Cu material (D) as alternative designs for the extended heat spreading layer to balance heat spreading with added weight. Note: dark regions=Cu (copper) material; light regions=FR-4 material.

In some implementations, PCB winding inductors may radially surround the power device area. For instance, and still referring to FIG. 10, power device section 504 is located at the center with PCB winding inductors surrounding the power section radially. Since PCB winding inductors are connected to each other in series using two layers only for connections, the rest of the layers are used for heat spreading and the shape of the Cu plane is optimized to increase heat spreading while minimizing weight. Compared to the case shown in FIG. 9, the radiative layout of the Cu (dark regions in the figure) can utilize more surface area for heat dissipation. Different amounts of allowable Cu (i.e., larger or smaller dark regions in FIG. 9) produce different designs while balancing the added weight.

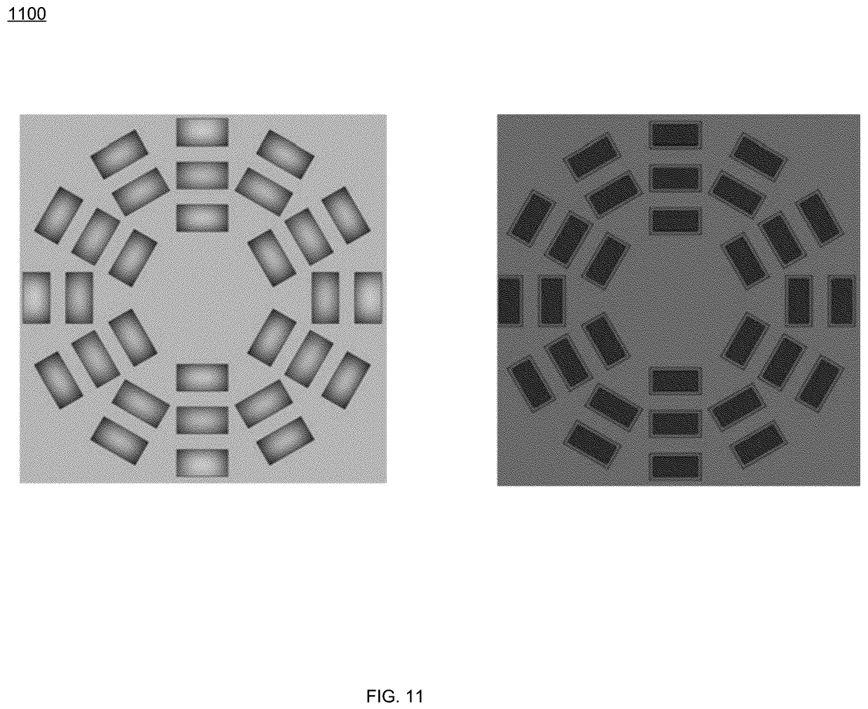

In some implementations, and referring at least to the example implementation of FIG. 11, rectifier design 1100 shows all spare areas that may be covered by copper, avoiding interfering inductor PCB windings. This example may further enhance the heat dissipation compared to FIG. 10; however, the trade-off is more copper consumption, increasing cost, weight and complexity. Ideally, an optimized copper path would use the minimum amount of copper with high thermal dissipation performance.

Therefore, without changing the planar size, the volume of the example rectifier may be reduced by more than 50% (in some implementations) while keeping the same electrical performance. The embedded PCB electronics design significantly reduces the work of device surface mounting. The whole fabrication process is highly standardized, and the design can be flexible for any customization by adjusting the number of inductance and relocating components. The thermal performance can be also improved due to the replacement of packaged devices with bare dies and direct heat spreading via PCB copper layers for thermal resistance reduction. The whole product is very compact and allows more design space for other electronics in EV wireless charging.

In general, embedded PCB technology offers multiple and non-limiting advantages for this application. For instance, compact size—the downsized power side allows for more efficient use of the space and can make it easier to integrate the power electronics into the receiver assembly with other components, such as the receiver coil, ferrite, enclosure, etc. As another example and non-limiting advantage, improved thermal performance—embedded PCBs can be designed with advanced thermal management features such as built-in heatsinks, which can help to dissipate heat more effectively. This can improve the performance and reliability of power electronics. As another example and non-limiting advantage, increased power density—within the same space, the higher power density power capability can enable high-power application. This may be important to EV charging-related development, as it may improve charging speed for reducing customers' anxiety about waiting and range. As another example and non-limiting advantage, cost-effectiveness—this embedded PCB rectifier can be manufactured using standard PCB fabrication techniques, which can be less expensive than other manufacturing methods. The only needed assembling work is adding ferrite cores to the board. As another example and non-limiting advantage, flexibility—this rectifier can be highly customizable which allows the creation of specific designs according to the application requirements. This can give more flexibility in the design process and allows for optimization the performance of the power electronics.

It will be appreciated that while the description describes wireless charging of an EV battery, the present disclosure may be extended to wirelessly charge other types of batteries. As such, the use of wirelessly charging EV batteries should be taken as example only and not to otherwise limit the scope of the present disclosure.

It will be appreciated that any standard PCB assembly/printing/fabrication, etc. equipment, as well as any other necessary equipment, may be used singly or in any combination with assembly process 10, which may be operatively connected to a computing device, such as the computing device shown in FIG. 2, to obtain their instructions. In one or more example implementations, the respective flowcharts may be manually-implemented, computer-implemented, or a combination thereof.

As will be appreciated by one skilled in the art after reading the present disclosure, the present disclosure may be embodied as a method, system, or computer program product. Accordingly, the present disclosure may take the form of an entirely hardware implementation, an entirely software implementation (including firmware, resident software, micro-code, etc.) or an implementation combining software and hardware aspects that may all generally be referred to herein as a “circuit,” “module” or “system.” Furthermore, the present disclosure may take the form of a computer program product on a computer-usable storage medium having computer-usable program code embodied in the medium.

Any suitable computer usable or computer readable medium may be utilized. The computer readable medium may be a computer readable signal medium or a computer readable storage medium. The computer-usable, or computer-readable, storage medium (including a storage device associated with a computing device or client electronic device) may be, for example, but is not limited to, an electronic, magnetic, optical, electromagnetic, infrared, or semiconductor system, apparatus, device, or any suitable combination of the foregoing. More specific examples (a non-exhaustive list) of the computer-readable medium may include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a media such as those supporting the internet or an intranet, or a magnetic storage device. Note that the computer-usable or computer-readable medium could even be a suitable medium upon which the program is stored, scanned, compiled, interpreted, or otherwise processed in a suitable manner, if necessary, and then stored in a computer memory. In the context of this document, a computer-usable or computer-readable, storage medium may be any tangible medium that can contain or store a program for use by or in connection with the instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. The computer readable program code may be transmitted using any appropriate medium, including but not limited to the internet, wireline, optical fiber cable, RF, etc. A computer readable signal medium may be any computer readable medium that is not a computer readable storage medium and that can communicate, propagate, or transport a program for use by or in connection with an instruction execution system, apparatus, or device.

Computer program code for carrying out operations of the present disclosure may be written in an object oriented programming language such as Java®, Smalltalk, C++ or the like. Java® and all Java-based trademarks and logos are trademarks or registered trademarks of Oracle and/or its affiliates. However, the computer program code for carrying out operations of the present disclosure may also be written in conventional procedural programming languages, such as the “C” programming language, PASCAL, or similar programming languages, as well as in scripting languages such as JavaScript, PERL, or Python. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through a local area network (LAN) or a wide area network (WAN), or the connection may be made to an external computer (for example, through the internet using an Internet Service Provider).

The flowchart and block diagrams in the figures illustrate the architecture, functionality, and operation of possible implementations of apparatus (systems), methods and computer program products according to various implementations of the present disclosure. It will be understood that each block in the flowchart and/or block diagrams, and combinations of blocks in the flowchart and/or block diagrams, may represent a module, segment, or portion of code, which comprises one or more executable computer program instructions for implementing the specified logical function(s)/act(s). These computer program instructions may be provided to a processor of a general purpose computer, special purpose computer, or other programmable data processing apparatus to produce a machine, such that the computer program instructions, which may execute via the processor of the computer or other programmable data processing apparatus, create the ability to implement one or more of the functions/acts specified in the flowchart and/or block diagram block or blocks or combinations thereof. It should be noted that, in some alternative implementations, the functions noted in the block(s) may occur out of the order noted in the figures. For example, two blocks shown in succession may, in fact, be executed substantially concurrently, or the blocks may sometimes be executed in the reverse order, depending upon the functionality involved.

These computer program instructions may also be stored in a computer-readable memory that can direct a computer or other programmable data processing apparatus to function in a particular manner, such that the instructions stored in the computer-readable memory produce an article of manufacture including instruction means which implement the function/act specified in the flowchart and/or block diagram block or blocks or combinations thereof.

The computer program instructions may also be loaded onto a computer or other programmable data processing apparatus to cause a series of operational steps to be performed (not necessarily in a particular order) on the computer or other programmable apparatus to produce a computer implemented process such that the instructions which execute on the computer or other programmable apparatus provide steps for implementing the functions/acts (not necessarily in a particular order) specified in the flowchart and/or block diagram block or blocks or combinations thereof.

The terminology used herein is for the purpose of describing particular implementations only and is not intended to be limiting of the disclosure. As used herein, the singular forms “a”, “an” and “the” are intended to include the plural forms as well, unless the context clearly indicates otherwise. As used herein, the language “at least one of A and B” (and the like) as well as “at least one of A or B” (and the like) should be interpreted as covering only A, only B, or both A and B, unless the context clearly indicates otherwise. It will be further understood that the terms “comprises” and/or “comprising,” when used in this specification, specify the presence of stated features, integers, steps (not necessarily in a particular order), operations, elements, and/or components, but do not preclude the presence or addition of one or more other features, integers, steps (not necessarily in a particular order), operations, elements, components, and/or groups thereof.

The terms “coupled,” “attached,” or “connected” used herein is to refer to any type of relationship, direct or indirect, between the components in question, and is to apply to electrical, mechanical, fluid, optical, electromagnetic, electromechanical, or other connections. Additionally, the terms “first,” “second,” etc. are used herein only to facilitate discussion, and carry no particular temporal or chronological significance unless otherwise indicated. The terms “cause” or “causing” means to make, force, compel, direct, command, instruct, and/or enable an event or action to occur or at least be in a state where such event or action is to occur, either in a direct or indirect manner.

The corresponding structures, materials, acts, and equivalents (e.g., of all means or step plus function elements) that may be in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. After reading the present disclosure, many modifications, variations, substitutions, and any combinations thereof will be apparent to those of ordinary skill in the art without departing from the scope and spirit of the disclosure. The implementation(s) were chosen and described in order to explain the principles of the disclosure and the practical application, and to enable others of ordinary skill in the art to understand the disclosure for various implementation(s) with various modifications and/or any combinations of implementation(s) as are suited to the particular use contemplated. The features of any dependent claim may be combined with the features of any of the independent claims or other dependent claims.

Having thus described the disclosure of the present application in detail and by reference to implementation(s) thereof, it will be apparent that modifications, variations, and any combinations of implementation(s) (including any modifications, variations, substitutions, and combinations thereof) are possible without departing from the scope of the disclosure defined in the appended claims.

What is claimed is:

1. A method comprising:
fabricating a rectifier, wherein fabricating the rectifier includes:
fabricating a power device area in a printed circuit board (PCB);
fabricating a passive component area in the PCB;
fabricating an inductor area in the PCB, wherein each component of the power device area, the passive component area, and copper windings of the inductor area is entirely embedded within the PCB; and
assembling one or more ferrite blocks into the PCB.

2. The method of claim 1, wherein fabricating the rectifier further includes fabricating, under an active power device area, a plurality of vias connecting a copper substrate to one or more copper layers of the PCB.

3. The method of claim 2, wherein the one or more copper layers of the PCB extend beyond the power device area and the passive component area.

4. The method of claim 1, wherein the power device area is located in a center portion of the PCB.

5. The method of claim 4, wherein PCB winding inductors radially surround the power device area.

6. The method of claim 1, wherein the power device area is located in a corner portion of the PCB.

7. The method of claim 1, wherein a cold plate is attached to a bottom copper layer of the PCB.

8. A computer program product residing on a computer readable storage medium having a plurality of instructions stored thereon which, when executed across one or more processors, causes at least a portion of the one or more processors to perform operations comprising:
fabricating a rectifier, wherein fabricating the rectifier includes:
fabricating a power device area in a printed circuit board (PCB);
fabricating a passive component area in the PCB;
fabricating an inductor area in the PCB, wherein each component of the power device area, the passive component area, and copper windings of the inductor area is entirely embedded within the PCB; and
assembling one or more ferrite blocks into the PCB.

9. The computer program product of claim 8, wherein fabricating the rectifier further includes fabricating, under an active power device area, a plurality of vias connecting a copper substrate to one or more copper layers of the PCB.

10. The computer program product of claim 9, wherein the one or more copper layers of the PCB extend beyond the power device area and the passive component area.

11. The computer program product of claim 8, wherein the power device area is located in a center portion of the PCB.

12. The computer program product of claim 11, wherein PCB winding inductors radially surround the power device area.

13. The computer program product of claim 8, wherein the power device area is located in a corner portion of the PCB.

14. The computer program product of claim 8, wherein a cold plate is attached to a bottom copper layer of the PCB.

15. An apparatus comprising:
a rectifier, wherein the rectifier includes:
a power device area in a printed circuit board (PCB);
a passive component area in the PCB;
an inductor area in the PCB, wherein each component of the power device area, the passive component area, and copper windings of the inductor area is entirely embedded within the PCB; and
one or more ferrite blocks in the PCB.

16. The apparatus of claim 15 further comprising a plurality of vias under an active power device area connecting a copper substrate to one or more copper layers of the PCB.

17. The apparatus of claim 16, wherein the one or more copper layers of the PCB extend beyond the power device area and the passive component area.

18. The apparatus of claim 15, wherein the power device area is located in a center portion of the PCB.

19. The apparatus of claim 18, wherein PCB winding inductors radially surround the power device area.

20. The apparatus of claim 15, wherein the power device area is located in a corner portion of the PCB.
